(19) United States
(12) Patent Application Publication
(10) Pub. No.: US 2014/0239238 A1
(43) Pub. Date: Aug. 28, 2014

(54) LEAD-FREE CONDUCTIVE PASTE COMPOSITION FOR SOLAR CELLS

(71) Applicants: Kosuke Tsunoda, Nagoya-shi (JP); Yuko Suzuki, Nagoya-shi (JP); Takayuki Aoyama, Nagoya-shi (JP)

(72) Inventors: Kosuke Tsunoda, Nagoya-shi (JP); Yuko Suzuki, Nagoya-shi (JP); Takayuki Aoyama, Nagoya-shi (JP)

(73) Assignee: NORITAKE CO., LIMITED, Nagoya-shi, Aichi (JP)

(21) Appl. No.: 14/348,806

(22) PCT Filed: Jul. 27, 2012
(86) PCT No.: PCT/JP2012/069258

§ 371 Date: Mar. 31, 2014

(30) Foreign Application Priority Data
Sep. 29, 2011 (JP) 2011-215443

(51) Int. Cl. H01L 31/0224

(52) U.S. Cl. CPC H01L 31/022425
USPC 252/514

(57) ABSTRACT

A lead-free conductive paste composition for a solar cell contains a conductive powder, a glass frit, and a vehicle, the glass frit including at least one type of lead-free glass containing Bi₂O₃ from 10 to 32 (mol %), ZnO from 15 to 30 (mol %), SiO₂ from 15 to 26 (mol %), B₂O₃ from 5 to 18 (mol %), Li₂O, Na₂O, and K₂O from 12 to 25 (mol %) in total, Al₂O₃ from 2 to 10 (mol %), TiO₂ from 0 to 6 (mol %), ZrO₂ from 0 to 5 (mol %), 0 to 6 (mol %) P₂O₅ and 0 to 4 (mol %) Sb₂O₃ making a total of 0 to 6 (mol %), and CeO₂ from 0 to 5 (mol %) at proportions within the respective ranges relative to the whole glass composition in terms of oxide.

### TECHNICAL FIELD

The present invention relates to a lead-free conductive paste composition preferred for a solar cell electrode formed by a fire-through method.

### BACKGROUND ART

For example, a typical silicon-based solar cell has a structure including an antireflection film and a light-receiving surface electrode via an n⁺ layer on an upper surface of a silicon substrate that is a p-type polycrystalline semiconductor and including a rear surface electrode (hereinafter simply referred to as an “electrode” when no distinction is made between these electrodes) via a p⁺ layer on a lower surface, and electric power generated by receiving light in p-n junction of the semiconductor is extracted through the electrodes. The antireflection film is for the purpose of reducing a surface reflectance while maintaining a sufficient visible light transmittance and is made up of a thin film of silicon nitride, titanium dioxide, silicon dioxide, etc.

The light-receiving surface electrode of the solar cell is formed with a method called fire-through, for example. In this electrode forming method, for example, after the antireflection film is disposed on the entire surface of the n⁺ layer, a conductive paste is applied in an appropriate shape onto the antireflection film by using a screen printing method, for example, and is subjected to firing treatment. This method simplifies the process as compared to the case of partially removing the antireflection film to form an electrode in the removed portion, and causes no problem of displacement between the removed portion and an electrode forming position. The conductive paste consists mainly of, for example, silver powder, glass fit (flaky or powdery fragments of glass formed by melting, quenching, and, if needed, crushing glass raw materials), an organic vehicle, and an organic solvent and, since a glass component in the conductive paste etches and breaks the antireflection film in the course of the firing, an ohmic contact is formed between a conductive component in the conductive paste and the n⁺ layer (see, e.g., Patent Document 1).

Therefore, it is desired for such light-receiving surface electrode formation to improve an ohmic contact and consequently increase a fill factor (FF value) and energy conversion efficiency, and various attempts have hitherto been made to achieve improvement for enhancing a fire-through property.

### PRIOR ART DOCUMENTS

### Patent Documents

Patent Document 1: Japanese Laid-Open Patent Publication No. 2006-332032

Patent Document 2: Japanese Laid-Open Patent Publication No. 2008-109016

Patent Document 3: Japanese Laid-Open Patent Publication No. 2006-313744

Patent Document 4: Japanese Unexamined Patent Application Publication (Translation of PCT Application) No. 2008-543080

Patent Document 5: Japanese Patent No.3534684

Patent Document 6: Japanese Laid-Open Patent Publication No. 2010-238958

Patent Document 7: Japanese Laid-Open Patent Publication No. 2010-173904

Patent Document 8: Japanese Laid-Open Patent Publication No. 2010-087501

Patent Document 9: Japanese Laid-Open Patent Publication No. 2009-231827

Patent Document 10: Japanese Laid-Open Patent Publication No. 2009-194141

Patent Document 11: WO 2007/102287

Patent Document 12: WO 2009/041182

Patent Document 13: Japanese Unexamined Patent Application Publication (Translation of PCT Application) No. 2011-502330

Patent Document 14: Japanese Unexamined Patent Application Publication (Translation of PCT Application) No. 2011-503772

Patent Document 15: Japanese Laid-Open Patent Publication No. 2011-035034

### SUMMARY OF THE INVENTION

### Problem to Be Solved by the Invention

Although lead-free glass without lead is increasingly used in various fields because of environmental concerns etc., lead glass is still mainly used for the above purpose. This is because if typical lead-free glass is used in conductive paste for forming a light-receiving surface electrode with the fire-through method, a firing temperature becomes higher than that in the case of using lead glass and a sufficient ohmic contact cannot be acquired, leading to poor electrical characteristics. Although various proposals have hitherto been made for improving the firing temperature and the fire-through property in the case of using lead-free glass, further improvement is still desired in the current situation.

For example, it is proposed to add a Zn-containing additive such as ZnO to enhance electrical performance in a conductive composition using lead-free glass fit consisting of Bi-based glass mainly composed of Bi₂O₃, B₂O₃, and SiO₂ (see Patent Document 1). The glass fit consists of 0.1 to 8 (wt %) SiO₂, 0 to 4 (wt %) Al₂O₃, 8 to 25 (wt %) B₂O₃, 0 to 1 (wt %) CaO, 0 to 42 (wt %) ZnO, 0 to 4 (wt %) Na₂O, 0 to 3.5 (wt %) Li₂O, 28 to 85 (wt %) Bi₂O₃, 0 to 3 (wt %) Ag₂O, 0 to 4.5 (wt %) CeO₂, 0 to 3.5 (wt %) SnO₂, and 0 to 15 (wt %) BiF₃, and it is described that this conductive composition preferably has an additive amount of the Zn-containing additive within a range up to 10 (wt %) of the whole composition and the average particle diameter less than 0.1 (μm). Although a smaller Zn-containing additive amount is preferable in terms of an adhesive force of an electrode etc., and a finer additive is preferable for acquiring the effect from a smaller amount, a small amount of a finer additive is associated with poor dispersibility and difficult to handle.

A silver paste for a solar cell element is proposed that uses glass frit with 5 to 10 (wt %) ZnO, 70 to 84 (wt %) Bi₂O₃, and 6 (wt %) or more B₂O₃+SiO₂ (see Patent Document 2). Although this silver paste is for the purpose of increasing strength of adhesive to a substrate and long-term reliability, even when the glass frit having the main components within the composition ranges described above is used, the adhesive strength is not necessarily acquired and sufficient electrical characteristics are not acquired.

A thick-film conductive composition containing metal particles of any of Al, Cu, Au, Ag, Pd, and Pt, or alloy thereof, or a mixture thereof, lead-free glass, and an organic medium is proposed as a composition using lead-free glass in solar cell electrode application (see Patent Document 3). The lead-free glass is described as having the composition containing SiO₂, B₂O₃, Bi₂O₃, ZnO, and Al₂O₃ at proportions within ranges of 0.5 to 35 (wt %), 1 to 15 (wt %), 55 to 90 (wt %), 0 to 15 (wt %), and 0 to 5 (wt %), respectively. Since a lead cannot be soldered if a rear surface electrode is made of Al and, on the other hand, a rear surface electric field is compromised if a bus bar is made of Ag or Ag/Al, this conductive composition is for the purpose of forming an electrode without these problems. However, this composition is for the purpose of improving the rear surface electrode and gives no consideration to the fire-through property, electrical characteristics, etc., when the composition is used in the light-receiving surface electrode and the composition has a problem of an excessively high softening point, for example.

A light-receiving surface electrode is proposed that contains 85 to 99 (wt %) conductive metal component and 1 to 15 (wt %) glass component with the glass component containing 5 to 85 (mol %) Bi₂O₃ and 1 to 70 (mol %) SiO₂ (see Patent Document 4). This light-receiving surface electrode is for the purpose of acquiring a sufficient ohmic contact at low firing temperature when lead-free glass is used and it is described that the glass component preferably contains V₂O₅; trivalent oxide such as Al and B; tetravalent oxide such as Ti and Z; pentavalent oxide such as P, Nb, and Sb; alkali oxide; alkaline-earth oxide; ZnO; and Ag₂O at proportions within ranges of 0.1 to 30 (mol %), 1 to 20 (mol %), 1 to 15 (mol %), 0.1 to 20 (mol %), 0.1 to 25 (mol %), 0.1 to 20 (mol %), 0.1 to 25 (mol %), and 0.1 to 12 (mol %), respectively. However, the glass composition described in claims is significantly wide and does not specify any composition suitable for the light-receiving surface electrode formation with fire-through. On the other hand, several specific glass compositions are described as embodiments, none of the glasses can be used for the light-receiving surface electrode because of insufficient electrical characteristics or an excessively high softening point.

In a proposed conductive paste, glass fit contains substantially no lead oxide and contains 9.0 to 20.0 (wt %) B₂O₃, 22.0 to 32.0 (wt %) SiO₂, 35.0 to 45.0 (wt %) BaO, 0.1 to 30.0 (wt %) ZnO, 0.1 to 12.0 (wt %) Al₂O₃, 0.1 to 15.0 (wt %) Na₂O, and the firing is performed at 600 to 670 (degrees C.) (see Patent Document 5). It is indicated that the glass fit preferably contains 0.01 to 10 (wt %) ZrO₂ and 0.01 to 6 (wt %) TiO₂. However, the conductive paste is a conductive paste for an external electrode of an electronic component. Since the firing of solar cells is generally performed at 700 to 800 (degrees C.), sufficient electrical characteristics are not acquired at 600 to 670 (degrees C.) and the conductive paste cannot be used for the light-receiving surface electrode formation with fire-through.

A conductive composition for the purpose of being used with fire-through is proposed that contains silver powder; lead-free bismuth-free glass powder having basicity of 0.3 to 1.0 and a glass-transition point of 400 to 550 (degrees C.) and containing B₂O₃, ZnO, and 20 to 50 (mol %) alkaline-earth metal oxide; and a vehicle consisting of an organic substance (see Patent Document 6). It is indicated that the glass powder preferably contains 20 to 70 (mol %) B₂O₃ and 0.1 to 60 (mol %) ZnO and preferably contains Fe₂O₃, TiO₂, SiO₂, Al₂O₃, ZrO₂, NiO within a range equal to or less than 5 (mol %). Although this conductive composition is for the purpose of ensuring electrical performance and adhesiveness to a substrate, since the composition does not contain bismuth, which is a heavy metal, in consideration of environmental load, sufficient electrical characteristics cannot be acquired because of a poor fire-through property and absence of a favorable ohmic contact.

A glass composition contained in a conductive paste for forming an electrode etc., of a solar cell is proposed and the glass composition does not contain PbO and SiO₂, contains 79 to 99.9 (wt %) Bi₂O₃, 0.1 to 5.2 (wt %) B₂O₃, and 0 to 11 (wt %) ZnO, and has a B₂O₃/Bi₂O₃ molar ratio of 0.007 to 0.375 (see Patent Document 7). It is also indicated that this glass may contain at least one of BaO, MgO, CaO, and SrO from 0 to 10 (wt %), Al₂O₃ from 0 to 10 (wt %), at least one of CeO₂, CuO, and Fe₂O₃ from 0 to 5 (wt %), and at least one of LiO₂, Na₂O, and K₂O from 0 to 2 (wt %). Although this glass is for the purpose of favorable flowage during a short heating time, the antireflection film is too strongly eroded because of an extremely high bismuth content rate and sufficient electrical characteristics cannot be acquired. Since SiO₂ is not contained, the composition has problems that chemical durability of glass becomes insufficient and that humidity resistance of the Ag electrode is not achieved.

A conductive composition for the purpose of being used with fire-through is proposed that contains silver powder, lead-free glass powder containing Bi₂O₃, B₂O₃, ZnO, and 10 to 50 (mol %) alkaline-earth metal oxide, and a vehicle consisting of an organic substance (see Patent Document 8). It is indicated that the glass powder preferably contains 10 to 65 (mol %) Bi₂O₃, 20 to 50 (mol %) B₂O₃, and 0.1 to 50 (mol %) ZnO and preferably contains SiO₂, Al₂O₃, ZrO₂, NiO within a range equal to or less than 2 (mol %). Although this conductive composition is for the purpose of achieving a favorable fire-through property, the antireflection film is too strongly eroded because of a high content of the alkaline-earth oxide and, therefore, sufficient electrical characteristics cannot be acquired. Due to low contents of SiO₂, Al₂O₃, and ZrO₂, the composition has problems that the chemical durability of glass becomes insufficient and that the humidity resistance of the Ag electrode is not achieved.

A conductive composition for the purpose of being used with fire-through is proposed that contains 70 to 95 (wt %) silver powder, 1 to 10 (wt %) glass powder having basicity of 0.16 to 0.44 and a glass-transition point of 300 to 450 (degrees C.) without PbO relative to 100 (wt %) silver powder, and a vehicle consisting of an organic substance (see Patent Document 9). It is indicated that the glass powder is preferably binary glass of Bi₂O₃—B₂O₃ and preferably contains TiO₂, SiO₂, Al₂O₃, ZrO₂, and NiO within a range of 0 to 5 (mol %). Although this conductive composition is for the purpose of ensuring electrical performance and adhesiveness to a substrate, due to low contents of SiO₂, Al₂O₃, and ZrO₂, the composition has problems that the chemical durability of glass becomes insufficient and that the humidity resistance of the Ag electrode is not achieved.

A conductive paste for solar cell electrode formation containing conductive particles of silver etc., glass fit, organic binder, and solvent is proposed and the glass fit or a paste additive contains alkaline-earth metal (at least one of Mg, Ca, Sr, and Ba) with a Pb content amount in the conductive paste equal to or less than 0.1 (wt %) (see Patent Document 10). It is indicated that a content amount of the alkaline-earth metal in the paste is preferably 0.1 to 10 (wt %) relative to 100 (wt %) conductive particles or is 5 to 55 (wt %) relative to the overall weight of the glass fit if contained in the glass frit. Although this conductive paste is for the purpose of attempting to achieve electrical characteristics and soldering strength, since the antireflection film is too strongly eroded because of a high content of the alkaline-earth metal, sufficient electrical characteristics cannot be acquired.

A conductive paste used for a solar cell light-receiving surface electrode is proposed and the conductive paste contains Ag powder, an organic vehicle, and a glass fit having a B₂O₃/SiO₂ molar ratio equal to or less than 0.3, a softening point of 570 to 760 (degrees C.), and 0 (mol %) or 20.0 (mol %) or less Bi₂O₃ (see Patent Document 11). It is indicated that the glass frit preferably contains Al₂O₃, TiO₂, and CuO at proportions equal to or less than 15 (mol %), 0 to 10 (mol %), and 0 to 15 (mol %), respectively, and that the conductive paste preferably contains ZnO, TiO₂, and ZrO₂ separately from the glass frit. Although this conductive paste is for the purpose of achieving high adhesive strength even.in the case of low-temperature firing and acquiring a light-receiving surface electrode with low contact resistance, since the softening point is too high, a favorable ohmic contact is difficult to achieve and sufficient electrical characteristics cannot be acquired. This is considered to be due to high contents of Al, Ti, and Si.

An Ag electrode paste is proposed that contains Ag powder, an organic vehicle, and lead-free glass fit containing 13 to 17 (wt %) SiO₂, 0 to 6 (wt %) B₂O₃, 65 to 75 (wt %) Bi₂O₃, 1 to 5 (wt %) Al₂O₃, 1 to 3 (wt %) TiO₂, and 0.5 to 2 (wt %) CuO (see Patent Document 12). Although this Ag electrode paste is for the purpose of forming a light-receiving surface electrode with low line resistance, since erosion of the antireflection film becomes too weak because of excessive SiO₂, sufficient electrical characteristics are not acquired.

A thick-film composition is proposed that has conductive silver powder, one or more glass frits, and an Mg-containing additive dispersed in an organic medium (see Patent Documents 13 and 14). It is indicated that at least one glass frit can be lead-free (Patent Document 13), that the Mg-containing additive preferably accounts for 0.1 to 10 (wt %) of the whole composition, that the thick-film composition may contain Zn, Gd, Ce, Zr, Ti, Mn, Sn, Ru, Co, Fe, Cu, and Cr, and that the glass frit preferably contains 8 to 25 (wt %) Bi₂O₃, B₂O₃ and may contain SiO₂, P₂O₅, GeO₂, and V₂O₅. Although this thick-film composition is for the purpose of improving the electrical performance of the solar cell electrode, since the erosion of the antireflection film becomes too weak because of a low Bi₂O₃ amount, sufficient electrical characteristics are not acquired.

Although various lead-free glass-based conductive paste compositions are proposed as described above, all the compositions have disadvantages such as difficulty in erosion control, insufficient chemical durability, and high contact resistance.

The present invention was conceived in view of the situations and it is therefore an object of the present invention to provide a lead-free conductive paste composition for a solar cell capable of forming an electrode with excellent electrical characteristics.

The applicant of the present application proposed a lead-free conductive composition for a solar cell electrode containing conductive powder, a glass frit, and a vehicle and the glass frit comprising at least one type of lead-free glass containing 10 to 29 (mol %) Bi₂O₃, 15 to 30 (mol %) ZnO, 0 to 20 (mol %) SiO₂, 20 to 33 (mol %) B₂O₃, and Li₂O, Na₂O, and K₂O in a total amount at a proportion within a range of 8 to 21 (mol %) relative to the whole glass composition in terms of oxide (see Patent Document 15). The glass frit preferably accounts for 2 to 6 (wt %) of the whole paste, and the conductive powder is preferably silver powder. The glass frit can contain Al₂O₃, P₂O₅, alkaline-earth metal oxide, and other compounds within a range equal to or less than 20 (mol %). This application proposes a paste composition capable of further enhancing chemical durability for this composition.

### Means for Solving the Problem

To achieve the object, the present invention provides a lead-free conductive paste composition for a solar cell containing a conductive powder, a glass frit, and a vehicle, the glass frit comprising at least one type of lead-free glass containing Bi₂O₃ from 10 to 32 (mol %), ZnO from 15 to 30 (mol %), SiO₂ from 15 to 26 (mol %), B₂O₃ from 5 to 18 (mol %), Li₂O, Na₂O, and K₂O from 12 to 25 (mol %) in total, Al₂O₃ from 2 to 10 (mol %), TiO₂ from 0 to 6 (mol %), ZrO₂ from 0 to 5 (mol %), 0 to 6 (mol %) P₂O₅ and 0 to 4 (mol %) Sb₂O₃ making a total of 0 to 6 (mol %), and CeO₂ from 0 to 5 (mol %) at proportions within the respective ranges relative to the whole glass composition in terms of oxide.

### Effects of the Invention

Consequently, since the lead-free conductive paste composition for a solar cell is made up of the glass fit comprising the lead-free glass having the composition, when the electrode of the solar cell is formed by using this paste composition, the electrode can be acquired that has excellent electrical characteristics and humidity resistance even though the electrode is lead-free. Also, it can be easily controlled that an electrode material penetrates into the p-n junction.

In the glass frit composition, Bi₂O₃ is a component lowering the softening point of glass and is essential for enabling low-temperature firing and achieving a favorable fire-through property. If Bi₂O₃ is less than 10 (mol %), since the softening point becomes too high and the antireflection film is hardly eroded, a favorable ohmic contact cannot be acquired and the chemical durability of glass is reduced. If Bi₂O₃ exceeds 32 (mol %), since the softening point becomes too low and makes the erosion of the antireflection film strong, the electrical characteristic of the solar cell becomes insufficient. To achieve electrical characteristics as high as possible, the Bi₂O₃ amount is preferably sufficiently low and is more preferably limited to 28 (mol %) or less. To sufficiently lower the softening point, the Bi₂O₃ amount is preferably larger and is preferably equal to or greater than 15 (mol %). Therefore, the range of 15 to 28 (mol %) is particularly preferable.

B₂O₃ is a glass forming oxide (i.e., a component making a skeleton of glass) and is an essential component for lowering the softening point of glass. If B₂O₃ is less than 5 (mol %), since glass becomes instable and the softening point becomes too high, the antireflection film is hardly eroded and a favorable ohmic contact cannot be acquired. If B₂O₃ exceeds 18 (mol %), the softening point becomes too low and, therefore, excessively strong erosion causes a problem of breakage of the p-n junction etc. Since a smaller amount of B₂O₃ makes the softening point higher while a larger amount of B₂O₃ makes the erodibility too strong, B₂O₃ is more preferably equal to or greater than 8 (mol %) and more preferably equal to or less than 16 (mol %). Therefore, the range of 8 to 16 (mol %) is particularly preferable.

ZnO is a component lowering the softening point of glass and enhancing the chemical durability, and ZnO less than 15 (mol %) makes the softening point too high and the durability insufficient. On the other hand, if ZnO exceeds 30 (mol %), since glass is easily crystallized and an open voltage Voc is lowered although affected by the balance with other components, the electrical characteristics of the solar cell become insufficient. Since a lower ZnO amount makes the softening point higher and the durability lower while a larger ZnO amount facilitates the crystallization, the amount is more preferably equal to or less than 30 (mol %). From the same viewpoint, the amount is further preferably equal to or greater than 21 (mol %) and further preferably equal to or less than 26 (mol %). Therefore, the range of 21 to 26 (mol %) is particularly preferable.

SiO₂ is a glass forming oxide and is a component essential for increasing the stability of glass and enhancing the chemical durability. SiO₂ less than 15 (mol %) makes the chemical durability insufficient and, on the other hand, if SiO₂ exceeds 26 (mol %), since the softening point becomes too high, the antireflection film is hardly eroded and a favorable ohmic contact cannot be acquired. SiO₂ is preferably equal to or greater than 17 (mol %) for acquiring higher stability and is preferably equal to or less than 22 (mol %) for limiting the softening point to a lower value. Therefore, 17 to 22 (mol %) is particularly preferable.

The alkali components Li₂O, Na₂O, and K₂O are components lowering the softening point of glass and, if the total amount is less than 12 (mol %), since the softening point becomes too high, the antireflection film is hardly eroded and, therefore, a favorable ohmic contact cannot be acquired. On the other hand, if the total amount exceeds 25 (mol %), alkali is eluted and the chemical durability is reduced and, since the antireflection film is too strongly eroded, the electrical characteristics of the solar cell become insufficient. Since a smaller alkali component amount makes the softening point higher while a larger alkali component amount makes the electrical characteristics lower, the total amount is more preferably equal to or greater than 13 (mol %) and more preferably equal to or less than 21 (mol %). Therefore, the range of 13 to 21 (mol %) is particularly preferable.

Al₂O₃ is an essential component increasing the stability of glass and enhancing the chemical durability. Al₂O₃ less than 2 (mol %) makes the chemical durability insufficient and, on the other hand, if Al₂O₃ exceeds 10 (mol %), the softening point becomes too high and the open voltage Voc is lowered. From these viewpoints, Al₂O₃ is more preferably equal to or greater than 3 (mol %) and more preferably equal to or less than 5.5 (mol %). Therefore, the range of 3 to 5.5 (mol %) is particularly preferable.

TiO₂ enhances the chemical durability of glass, has an effect of increasing an FF value, and is therefore preferably contained although not an essential component. If TiO₂ exceeds 6 (mol %), since the softening point becomes too high and the antireflection film is hardly eroded, a favorable ohmic contact cannot be acquired. To suppress a rise in the softening point as low as possible, TiO₂ is preferably limited to 3 (mol %) or less.

ZrO₂ enhances the chemical durability of glass, has an effect of increasing an FF value, and is therefore preferably contained although not an essential component. If ZrO₂ exceeds 5 (mol %), since the softening point becomes too high and the antireflection film is hardly eroded, a favorable ohmic contact cannot be acquired. To suppress a rise in the softening point as low as possible, ZrO₂ is preferably limited to 3 (mol %) or less.

P₂O₅ and Sb₂O₃ are donor elements for an n layer and are contained for ensuring the ohmic contact of the light-receiving surface electrode although not essential components. P₂O₅ exceeding 6 (mol %) or Sb₂O₃ exceeding 4 (mol %) makes glass less meltable and tends to generate a dead layer (layer with high recombination rate) and, therefore, P₂O₅ and Sb₂O₃ are preferably limited to 6 (mol %) or less and 4 (mol %) or less, respectively. Although both may be contained together, a total amount is preferably limited to 6 (mol %) or less in this case.

To ensure the ohmic contact, it is desirable to allow a donor element to form a solid solution at high concentration. In the case of a cell with high sheet resistance making up a shallow emitter, it is desirable to set the thickness dimension of the antireflection film consisting of, for example, Si₃N₄, to about 80 (nm) and to control an amount of erosion by an electrode within the range of 80 to 90 (nm), i.e., at the accuracy within 10 (nm). However, such control is extremely difficult and control must inevitably be provided such that slightly excessive erosion occurs. Therefore, the eroded n layer is complemented with a donor element to suppress output reduction due to the excessive erosion. To ensure the ohmic contact under such a condition, it is desirable to set the concentration of the donor element equal to or greater than 10¹⁹ (pieces/cm³), preferably, 10²⁰ (pieces/cm³); however, elements capable of achieving such a high concentration other than glass components such as Li are not found except As, P, and Sb. Among these elements, As is highly toxic and is desirably avoided in glass production operated in an open system. Therefore, the element added for ensuring the ohmic contact is limited to P and Sb.

The shallow emitter is formed by reducing a thickness of an n layer located on the light-receiving surface side to lower a surface recombination rate such that more electric current can be extracted. The formation of the shallow emitter causes the short wavelength side, particularly, near 400 (nm), to contribute to electric generation and, therefore, this is considered as an ideal solution in terms of improvement in efficiency of a solar cell. Since the shallow emitter has a thinner n-layer thickness of 70 to 100 (nm) on the light-receiving surface side as compared to 100 to 200 (nm) of a conventional silicon solar cell and reduces a portion of electricity generated by receiving light and unable to be effectively utilized because of conversion into heat before reaching the p-n junction, a short-circuit current increases and, consequently, the electric generation efficiency is advantageously enhanced.

However, since a cell must have higher sheet resistance, the shallow emitter reduces donor element (e.g., phosphorus) concentration in the vicinity of a surface or makes the p-n junction shallow. The reduction in the donor element concentration in the vicinity of a surface increases a barrier between Ag and Si and makes it difficult to ensure the ohmic contact of a light-receiving surface electrode. The shallow p-n junction makes it very difficult to provide penetration depth control such that an antireflection film is sufficiently broken by fire-through while an electrode is prevented from penetrating into the p-n junction. The paste composition of the present invention is preferably applied to the shallow emitter and more preferably has glass composition or paste composition containing a donor element as described above.

CeO₂ has an effect of restraining Bi₂O₃ from being reduced and turned to metal Bi during glass melting and acts as an oxidizing agent and is therefore preferably contained although not an essential component. However, if CeO₂ exceeds 5 (mol %), since the softening point becomes too high and the antireflection film is hardly eroded, a favorable ohmic contact cannot be acquired. CeO₂ is preferably contained at 0.1 (mol %) or more to certainly achieve a reduction restraining effect and is preferably limited to 3 (mol %) or less to sufficiently suppress the rise in the softening point. Therefore, the range of 0.1 to 3 (mol %) is particularly preferable.

The alkaline-earth oxides such as BaO, CaO, MgO, and SrO have effects of lowering the softening point of glass and suppressing the crystallization of glass although not essential components. However, since an amount exceeding 20 (mol %) of the alkaline-earth oxides reduces the chemical durability, it is desirable to include one or more of BaO, CaO, MgO, and SrO in a total amount equal to or less than 20 (mol %), for example, within a range of 0.1 to 20 (mol %). Among these alkaline-earth oxides, BaO is particularly preferable.

SO₂ has an effect of reducing the viscosity of glass although not an essential component. However, if SO₂ exceeds 6 (mol %), since the softening point becomes too high and the antireflection film is hardly eroded, a favorable ohmic contact cannot be acquired. Therefore, the SO₂ amount is appropriately equal to or less than 6 (mol %), for example, within a range of 0.1 to 6 (mol %) and is desirably within a range of 0.1 to 5 (mol %).

Although it is not necessarily easy to identify forms of the components contained in glass, all the proportions of these components are defined as oxide-converted values.

The glass making up the conductive composition of the present invention may contain other various glass constituent components and additives within a range not deteriorating the characteristics thereof. For example, an oxidizing agent such as SnO₂, CuO, and Ag₂O, a glass forming oxide such as GeO₂ and V₂O₅, and other compounds may be contained. If a large amount of these components and additives is contained, the electrical characteristics of a solar cell are deteriorated and, therefore, these components and additives may be contained within the range equal to or less than 20 (mol %) in total, for example.

Preferably, in the lead-free conductive paste composition for a solar cell, the glass frit has an average particle diameter equal to or less than 3.0 (μm). This enables acquisition of a conductive composition capable of achieving more favorable printability and a higher FF value. For example, an average particle diameter equal to or greater than 0.5 (μm) makes the dispersibility more excellent at the time of preparing the paste and therefore can increase productivity.

Preferably, the lead-free conductive paste composition for a solar cell contains the glass fit at a proportion within a range of 2 to 6 (wt %) relative to the whole paste. A larger glass fit amount makes the meltability of the antireflection film higher and enhances the fire-through property; however, the larger amount of the glass frit makes a resistance value higher and solar cell output lower. Therefore, the amount is preferably equal to or greater than 2 (wt %) for acquiring a sufficiently high fire-through property, while the amount is preferably equal to or less than 6 (wt %) for acquiring sufficiently high solar cell output.

Preferably, the conductive powder is silver powder. Although copper powder, nickel powder, etc. may be used as the conductive powder, the silver powder is most preferable because of higher electric conductivity.

Preferably, the lead-free conductive paste composition for a solar cell contains the silver powder and the vehicle at proportions within ranges of 74 to 92 parts by weight and 5 to 20 parts by weight, respectively. This leads to the acquisition of the conductive composition having favorable printability and high conductivity and enabling the fabrication of an electrode with favorable solder wettability. If the amount of silver powder is too small, high conductivity cannot be acquired and if the amount of the silver powder is excessive, the flowability is reduced, deteriorating the printability. If the amount of glass frit is too small, the adhesiveness to a substrate becomes insufficient and if the amount of the glass frit is excessive, glass floats on the electrode surface after firing, deteriorating the solder wettability.

The silver powder is not particularly limited and the powder of any shape such as a spherical shape or a scale shape may be used for enjoying the basic effect of the present invention that expands an optimum firing temperature range. However, for example, if spherical powder is used, since excellent printability is achieved and a filling rate of the silver powder is increased in an applied film, and additionally because highly-conductive silver is used, the electric conductivity of the electrode generated from the applied film is increased as compared to the case of using the silver powder of another shape such as a scale shape. As a result, a line width can be made narrower while ensuring necessary electric conductivity. Therefore, if this conductive composition is applied to the light-receiving surface electrode to make the line width narrower, a light-receiving area capable of absorbing solar energy can be further made larger and, thus, a solar cell with higher conversion efficiency can be acquired.

The conductive composition of the present invention may preferably control the diffusion of silver at the time of electrode formation with fire-through as described above and thus may preferably be used for the light-receiving surface electrode. However, the conductive composition is usable not only for the light-receiving surface electrode but also for a rear surface electrode. For example, the rear surface electrode is made up of an aluminum film covering the entire surface and an electrode in a belt shape etc., overlapping with the film, and the conductive composition is preferable for a constituent material of the belt-like electrode.

The glass frit can be synthesized from various vitrifiable raw materials within the composition ranges including, for example, oxide, hydroxide, carbonate, and nitrate, and for example, bismuth oxide, zinc oxide, silicon dioxide, boric acid, aluminum oxide, lithium carbonate, sodium carbonate, and potassium carbonate may be used as sources of Bi, Zn, Si, B, Al, Li, Na, and K, respectively.

### BRIEF DESCRIPTION OF THE DRAWINGS

FIG. 1 is a schematic of a cross section structure of a solar cell in which a paste composition for an electrode of an embodiment of the present invention is applied to a light-receiving surface electrode formation.

FIG. 2 is a diagram illustrating an example of a pattern for the light-receiving surface electrode of the solar cell of FIG. 1.

### MODES FOR CARRYING OUT THE INVENTION

An embodiment of the present invention will now be described in detail with reference to the drawings. In the following embodiment, diagrams are simplified or modified as needed and dimensional ratios and shapes of portions are not necessarily exactly depicted.

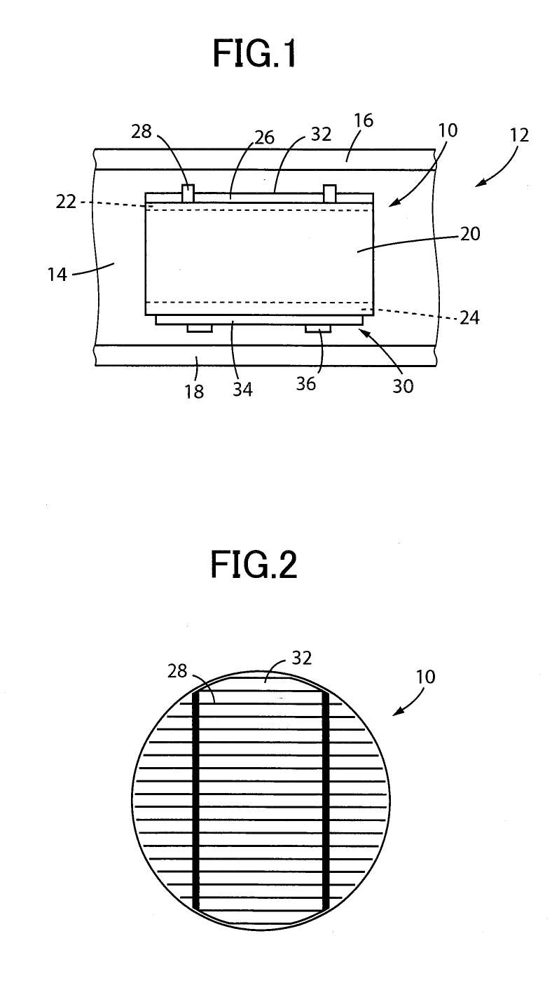

FIG. 1 is a schematic of a cross section structure of a solar cell module 12 including a silicon-based solar cell 10 to which a conductive composition of an embodiment of the present invention is applied. In FIG. 1, the solar cell module 12 includes the solar cell 10, a sealing material 14 sealing the solar cell 10, a surface glass 16 disposed on the sealing material 14 on the light-receiving surface side, and a protective film (i.e., back seat) 18 disposed for protecting the solar cell 10 and the sealing material 14 from the rear surface side. The sealing material 14 is made of EVA, for example, and contains a crosslinking agent, an ultraviolet absorbing agent, an adhesive protective agent, etc., as needed, so as to have sufficient weather resistance. For example, the protective film 18 is formed by laminating several resin films made of fluorine resin, polyethylene-terephthalate (PET) resin, or PET, EVA, etc., and has high weather resistance, water vapor barrier property, etc.

The solar cell 10 includes a silicon substrate 20 that is, for example, a p-type polycrystalline semiconductor, an n layer 22 and a p⁺ layer 24 formed respectively on the upper and lower surfaces thereof, an antireflection film 26 and a light-receiving surface electrode 28 formed on the n layer 22, and a rear surface electrode 30 formed on the p⁺ layer 24. The thickness dimension of the silicon substrate 20 is about 100 to 200 (μm), for example.

The n layer 22 and the p⁺ layer 24 are disposed by forming layers having high impurity concentrations on the upper and lower surfaces of the silicon substrate 20, and the thickness dimensions of the high concentration layers are about 70 to 100 (nm) for the n layer 22, for example, and about 500 (nm) for the p⁺ layer 24, for example. Although the thickness dimension of an n layer 22 is about 100 to 200 (nm) in a typical silicon-based solar cell, the n layer 22 of this embodiment has a thinner thickness and forms a structure called shallow emitter. The impurity contained in the n layer 22 is an n-type dopant, for example, phosphorus (P), and the impurity contained in the p⁺ layer 24 is a p-type dopant, for example, aluminum (Al) or boron (B).

The antireflection film 26 is, for example, a thin film made of silicon nitride Si₃N₄ etc., and is disposed with, for example, an optical thickness of about ¼ of the visible light wavelength, for example, about 80 (nm), to have an extremely low reflectance equal to 10(%) or less, for example, about 2(%).

The light-receiving surface electrode 28 consists of a thick film conductor having a uniform thickness dimension, for example, and is disposed in a comb-like planar shape having a multiplicity of thin line portions on substantially the entire surface of a light-receiving surface 32 as depicted in FIG. 2.

The thick film conductor is made of a thick film silver containing Ag and glass and the glass is lead-free glass containing, at proportions in terms of oxide, Bi₂O₃ within the range of 10 to 32 (mol %), ZnO within the range of 15 to 30 (mol %), SiO₂ within the range of 15 to 26 (mol %), B₂O₃ within the range of 5 to 18 (mol %), Li₂O, Na₂O, and K₂O within the range of 12 to 25 (mol %) in total, Al₂O₃ within the range of 2 to 10 (mol %), TiO₂ within the range of 0 to 6 (mol %), ZrO₂ within the range of 0 to 5 (mol %), P₂O₅ within the range of 0 to 6 (mol %), Sb₂O₃ within the range of 0 to 4 (mol %) (provided that a total amount of P₂O₅ and Sb₂O₃ is 0 to 6 (mol %)), and CeO₂ within the range of 0 to 5 (mol %). The lead-free glass can contain at least one of alkaline-earth oxides BaO, CaO, MgO, and SrO as an arbitrarily added component within a range equal to or less than 20 (mol %) in total and can contain SO₂ within a range equal to or less than 6 (mol %).

The thickness dimension of the conductive layer is, for example, within a range of 20 to 30 (μm), for example, about 25 (μm), and each of the thin line portions has a width dimension, for example, within a range of 80 to 130 (μm), for example, about 100 (μm), and has sufficiently high electric conductivity.

The rear surface electrode 30 is made up of an entire surface electrode 34 formed by applying a thick film material having aluminum as a conductive component onto substantially the entire surface of the p⁺ layer 16 and a belt-like electrode 36 made of a thick film silver applied in a belt shape onto the entire surface electrode 34. The belt-like electrode 36 is disposed for the purpose of enabling soldering of conductive wires etc., to the rear surface electrode 30.

The solar cell 10 configured as described above has the light-receiving surface electrode 28 made up of a thick film silver containing the lead-free glass with the composition described above within a range of 2 to 6 (wt %) as described above and therefore advantageously has excellent electrical characteristics as compared to a solar cell formed by using conventional lead-free glass and has an FF value equal to or greater than 75(%), which is at the same level as the case of using lead glass, for example.

The light-receiving surface electrode 28 as described above is formed by using a paste for an electrode consisting of conductive powder, glass fit, a vehicle, and solvent, for example, with a well-known fire-through method. An example of a method of manufacturing the solar cell 10 including the light-receiving surface electrode formation will hereinafter be described along with a method of manufacturing a paste for an electrode of comparison examples.

First, the glass frit is manufactured. For example, after preparing bismuth oxide, zinc oxide, silicon dioxide, boric acid, lithium carbonate, sodium carbonate, potassium carbonate, aluminum oxide, titanium oxide, zirconium oxide, ammonium phosphate, antimony oxide, calcium carbonate, barium carbonate, magnesium oxide, strontium carbonate, and ammonium sulfate as sources of Bi, Zn, Si, B, Li, Na, K, Al, Ti, Zr, P, Sb, Ca, Ba, Mg, Sr, and S, respectively, these sources are weighed and blended so as to form compositions described as embodiments in Table 1 and Table 3. Table 2 describes evaluation results of comparison examples out of the range of the present invention (claim 1) and Table 4 includes sample Nos. 18 and 19 indicative of evaluation results of a comparison example out of the range of claim 3 of the present invention and a comparison example out of the range of claims 1 and 2 of the present invention, respectively. Tables 3 and 4 correspond to the case of containing any of BaO, CaO, MgO, SrO, and SO₂, and Tables 1 and 2 correspond to the case of containing none of BaO, CaO, MgO, SrO, and SO₂. The raw materials may be oxide, hydroxide, carbonate, or nitrate, and pulverized raw materials are more easily melted and preferable. The raw materials are put into a crucible, melted for about 15 minutes to one hour at a temperature within a range of 900 to 1400 (degrees C.) depending on composition, and vitrified. The acquired glass was crushed by using a suitable crushing device such as a pot mill to acquire powder with an average particle diameter of about 0.4 to 4.0 (μm).

TABLE 1
[EMBODIMENT]

| | COMPOSITION (mol %) | | | | | | | | | | | | | | HUMIDITY |
|---|---|---|---|---|---|---|---|---|---|---|---|---|---|---|---|
| No. | Bi₂O₃ | B₂O₃ | SiO₂ | Al₂O₃ | ZnO | Li₂O | Na₂O | K₂O | P₂O₅ | Sb₂O₃ | TiO₂ | ZrO₂ | CeO₂ | FF (%) | RESISTANCE |
| 1 | 10.0 | 12.0 | 20.0 | 3.0 | 30.0 | 17.0 | 8.0 | — | — | — | — | — | — | 75 | — |
| 2 | 15.0 | 12.0 | 20.0 | 3.0 | 28.5 | 15.0 | 6.5 | — | — | — | — | — | — | 77 | ◯ |
| 3 | 23.0 | 12.0 | 20.0 | 3.0 | 24.0 | 14.0 | 3.0 | — | 1.0 | — | — | — | — | 77 | — |
| 4 | 28.0 | 12.0 | 20.0 | 3.0 | 20.0 | 17.0 | — | — | — | — | — | — | — | 77 | — |
| 5 | 32.0 | 12.0 | 20.0 | 3.0 | 15.0 | 18.0 | — | — | — | — | — | — | — | 75 | ◯ |
| 6 | 23.0 | 5.0 | 21.0 | 5.0 | 29.0 | 12.0 | 3.0 | — | 2.0 | — | — | — | — | 76 | ◯ |
| 7 | 26.0 | 8.0 | 17.0 | 3.0 | 29.0 | 12.0 | 3.0 | — | 2.0 | — | — | — | — | 77 | ◯ |
| 8 | 26.0 | 16.0 | 15.0 | 3.0 | 23.0 | 12.0 | 3.0 | — | 2.0 | — | — | — | — | 77 | — |
| 9 | 27.0 | 18.0 | 16.0 | 3.0 | 19.0 | 12.0 | 3.0 | — | 2.0 | — | — | — | — | 75 | Δ |
| 10 | 27.0 | 14.0 | 22.0 | 3.0 | 15.0 | 14.0 | 4.0 | — | 1.0 | — | — | — | — | 75 | Δ |
| 11 | 21.0 | 14.0 | 22.0 | 3.0 | 21.0 | 14.0 | 4.0 | — | 1.0 | — | — | — | — | 76 | — |
| 12 | 17.0 | 14.0 | 21.0 | 3.0 | 26.0 | 14.0 | 4.0 | — | 1.0 | — | — | — | — | 77 | ◯ |
| 13 | 15.0 | 13.0 | 20.0 | 3.0 | 30.0 | 14.0 | 4.0 | — | 1.0 | — | — | — | — | 75 | — |
| 14 | 18.0 | 17.0 | 15.0 | 3.0 | 30.0 | 10.0 | — | 5.0 | 2.0 | — | — | — | — | 75 | Δ |
| 15 | 20.0 | 12.0 | 18.0 | 3.0 | 30.0 | 10.0 | — | 5.0 | 2.0 | — | — | — | — | 76 | — |
| 16 | 25.0 | 12.0 | 22.0 | 3.0 | 21.0 | 10.0 | — | 5.0 | 2.0 | — | — | — | — | 77 | ◯ |
| 17 | 29.0 | 9.0 | 26.0 | 3.0 | 16.0 | 10.0 | — | 5.0 | 2.0 | — | — | — | — | 76 | — |
| 18 | 22.5 | 16.0 | 15.0 | 2.0 | 27.0 | 9.0 | 6.0 | — | 2.0 | — | — | 0.5 | — | 76 | ◯ |
| 19 | 24.0 | 12.5 | 15.0 | 7.0 | 24.0 | 9.0 | 6.0 | — | 2.0 | — | — | 0.5 | — | 75 | — |
| 20 | 26.0 | 9.0 | 15.0 | 10.0 | 22.5 | 9.0 | 6.0 | — | 2.0 | — | — | 0.5 | — | 75 | — |
| 21 | 31.0 | 12.0 | 20.0 | 3.0 | 21.0 | 12.0 | — | — | — | 1.0 | — | — | — | 75 | — |
| 22 | 30.0 | 12.0 | 20.0 | 3.0 | 21.0 | 12.0 | 1.0 | — | — | 1.0 | — | — | — | 76 | ◯ |
| 23 | 23.0 | 12.0 | 20.0 | 3.5 | 24.4 | 12.0 | 2.0 | — | 2.0 | — | — | 0.5 | 0.6 | 77 | ◯ |
| 24 | 26.0 | 12.0 | 20.0 | 3.0 | 20.0 | 12.0 | 4.0 | 2.0 | — | 1.0 | — | — | — | 77 | — |
| 25 | 23.0 | 12.0 | 20.0 | 3.0 | 20.0 | 16.0 | — | 5.0 | — | 1.0 | — | — | — | 76 | ◯ |
| 26 | 20.0 | 12.0 | 20.0 | 3.0 | 19.0 | 18.0 | 7.0 | — | — | 1.0 | — | — | — | 75 | — |
| 27 | 15.0 | 18.0 | 16.0 | 5.5 | 27.5 | 13.0 | — | 4.0 | 1.0 | — | — | — | — | 76 | ◯ |
| 28 | 17.0 | 17.0 | 16.0 | 5.5 | 24.5 | 13.0 | — | 4.0 | 3.0 | — | — | — | — | 77 | — |
| 29 | 21.0 | 14.0 | 16.0 | 5.5 | 20.5 | 13.0 | — | 4.0 | 6.0 | — | — | — | — | 75 | — |
| 30 | 16.0 | 18.0 | 18.0 | 3.0 | 27.0 | 10.0 | 7.0 | — | — | 1.0 | — | — | — | 76 | — |
| 31 | 16.0 | 18.0 | 18.0 | 3.0 | 26.0 | 10.0 | 7.0 | — | 1.0 | 1.0 | — | — | — | 76 | ◯ |
| 32 | 19.0 | 16.0 | 18.0 | 3.0 | 22.0 | 10.0 | 7.0 | — | 1.0 | 4.0 | — | — | — | 76 | — |
| 33 | 19.0 | 16.0 | 18.0 | 3.0 | 23.0 | 10.0 | 7.0 | — | — | 4.0 | — | — | — | 75 | — |
| 34 | 24.0 | 16.5 | 15.0 | 3.0 | 24.0 | 11.0 | — | 4.0 | 2.0 | — | 0.5 | — | — | 77 | ◯ |
| 35 | 26.0 | 16.5 | 15.0 | 3.0 | 19.5 | 11.0 | — | 4.0 | 2.0 | — | 3.0 | — | — | 76 | — |
| 36 | 28.0 | 14.0 | 15.0 | 3.0 | 17.0 | 11.0 | — | 4.0 | 2.0 | — | 6.0 | — | — | 76 | — |
| 37 | 24.0 | 16.5 | 15.0 | 3.0 | 24.0 | 11.0 | — | 4.0 | 2.0 | — | — | 0.5 | — | 77 | ◯ |
| 38 | 26.0 | 16.5 | 15.0 | 3.0 | 19.5 | 11.0 | — | 4.0 | 2.0 | — | — | 3.0 | — | 76 | — |
| 39 | 28.0 | 14.0 | 15.0 | 3.0 | 18.0 | 11.0 | — | 4.0 | 2.0 | — | — | 5.0 | — | 75 | — |
| 40 | 25.0 | 12.0 | 20.5 | 5.0 | 21.9 | 12.0 | 3.0 | — | — | — | 0.5 | — | 0.1 | 77 | — |
| 41 | 25.0 | 12.0 | 20.5 | 5.0 | 20.0 | 12.0 | 3.0 | — | — | — | 0.5 | — | 2.0 | 77 | ◯ |
| 42 | 25.0 | 12.0 | 20.5 | 5.0 | 17.0 | 12.0 | 3.0 | — | — | — | 0.5 | — | 5.0 | 75 | — |

TABLE 2
[COMPARISON EXAMPLE]

| | COMPOSITION (mol %) | | | | | | | | | | | | | | HUMIDITY |
|---|---|---|---|---|---|---|---|---|---|---|---|---|---|---|---|
| No. | Bi₂O₃ | B₂O₃ | SiO₂ | Al₂O₃ | ZnO | Li₂O | Na₂O | K₂O | P₂O₅ | Sb₂O₃ | TiO₂ | ZrO₂ | CeO₂ | FF (%) | RESISTANCE |
| 1 | 8.0 | 13.0 | 21.0 | 3.0 | 30.0 | 20.0 | 5.0 | — | — | — | — | — | — | 73 | — |
| 2 | 34.0 | 12.0 | 20.0 | 3.0 | 15.0 | 16.0 | — | — | — | — | — | — | — | 74 | — |
| 3 | 23.0 | 2.0 | 22.0 | 6.0 | 30.0 | 12.0 | 3.0 | — | 2.0 | — | — | — | — | 74 | — |
| 4 | 27.0 | 20.0 | 15.0 | 3.0 | 18.0 | 12.0 | 3.0 | — | 2.0 | — | — | — | — | 74 | X |
| 5 | 28.0 | 15.0 | 23.0 | 3.0 | 12.0 | 14.0 | 4.0 | — | 1.0 | — | — | — | — | 74 | X |
| 6 | 15.0 | 13.0 | 18.0 | 3.0 | 32.0 | 14.0 | 4.0 | — | 1.0 | — | — | — | — | 74 | — |
| 7 | 17.0 | 18.0 | 12.0 | 6.0 | 30.0 | 10.0 | — | 5.0 | 2.0 | — | — | — | — | 74 | X |
| 8 | 29.0 | 8.0 | 28.0 | 3.0 | 15.0 | 10.0 | — | 5.0 | 2.0 | — | — | — | — | 74 | — |
| 9 | 20.0 | 18.0 | 15.0 | — | 29.5 | 9.0 | 6.0 | — | 2.0 | — | — | 0.5 | — | 74 | X |
| 10 | 28.0 | 7.0 | 15.0 | 12.0 | 20.5 | 9.0 | 6.0 | — | 2.0 | — | — | 0.5 | — | 74 | — |
| 11 | 32.0 | 12.0 | 19.0 | 3.0 | 23.0 | 10.0 | — | — | — | 1.0 | — | — | — | 74 | ◯ |
| 12 | 18.0 | 12.0 | 20.0 | 3.0 | 19.0 | 20.0 | 7.0 | — | — | 1.0 | — | — | — | 73 | X |
| 13 | 23.0 | 11.5 | 16.0 | 5.5 | 19.0 | 13.0 | — | 4.0 | 8.0 | — | — | — | — | 74 | — |
| 14 | 20.0 | 15.0 | 17.0 | 3.0 | 22.0 | 10.0 | 7.0 | — | — | 6.0 | — | — | — | 74 | — |
| 15 | 29.0 | 12.0 | 15.0 | 3.0 | 16.0 | 11.0 | — | 4.0 | 2.0 | — | 8.0 | — | — | 74 | — |
| 16 | 30.0 | 12.0 | 15.0 | 3.0 | 16.0 | 11.0 | — | 4.0 | 2.0 | — | — | 7.0 | — | 73 | ◯ |
| 17 | 25.0 | 12.0 | 18.5 | 5.0 | 17.0 | 12.0 | 3.0 | — | — | — | 0.5 | — | 7.0 | 73 | — |

TABLE 3
[EMBODIMENT]

| | COMPOSITION (mol %) | | | | | | | | | | |
|---|---|---|---|---|---|---|---|---|---|---|---|
| No. | Bi₂O₃ | B₂O₃ | SiO₂ | Al₂O₃ | ZnO | CaO | BaO | MgO | SrO | Li₂O | Na₂O |
| 43 | 19.0 | 12.0 | 20.0 | 3.0 | 24.8 | — | — | — | — | 12.0 | 2.0 |
| 44 | 20.0 | 12.0 | 15.0 | 3.0 | 22.9 | 2.0 | 2.0 | — | 1.0 | 12.0 | 2.0 |
| 45 | 20.0 | 12.0 | 15.0 | 3.0 | 22.9 | 3.0 | 1.0 | 1.0 | — | 12.0 | 2.0 |
| 46 | 21.0 | 12.0 | 15.0 | 3.0 | 20.9 | — | 6.0 | — | — | 12.0 | 2.0 |
| 47 | 19.0 | 12.0 | 20.0 | 3.0 | 23.9 | — | — | — | — | 12.0 | 2.0 |
| 48 | 19.0 | 12.0 | 20.0 | 3.0 | 19.9 | — | — | — | — | 12.0 | 2.0 |
| 49 | 20.0 | 12.0 | 18.0 | 3.0 | 30.0 | 0.2 | — | — | — | 12.0 | 1.0 |
| 50 | 21.0 | 12.0 | 20.0 | 3.0 | 25.0 | — | 2.0 | — | — | 12.0 | 2.0 |
| 51 | 15.0 | 15.0 | 20.0 | 3.0 | 24.0 | — | 6.0 | — | — | 12.0 | 2.0 |
| 52 | 18.0 | 12.0 | 20.0 | 3.0 | 17.0 | — | 7.0 | 8.0 | — | 10.0 | 2.5 |
| 53 | 18.0 | 12.0 | 20.0 | 3.0 | 17.0 | 5.0 | 10.0 | — | — | 10.0 | 3.0 |
| 54 | 15.0 | 14.0 | 16.0 | 5.0 | 22.0 | 6.0 | 6.0 | — | — | 12.0 | 2.0 |
| 55 | 25.0 | 12.0 | 20.0 | 5.0 | 20.0 | 2.0 | 3.0 | — | — | 13.0 | — |
| 56 | 21.0 | 16.0 | 18.0 | 4.0 | 17.0 | — | — | 10.0 | — | 10.0 | 2.0 |
| 57 | 20.0 | 12.0 | 18.0 | 3.0 | 21.0 | — | 4.0 | — | 6.0 | 12.0 | 1.0 |
| 58 | 22.0 | 12.0 | 20.0 | 5.0 | 20.0 | 2.0 | 3.0 | 2.0 | — | 12.0 | 1.0 |
| 59 | 16.0 | 13.0 | 18.0 | 4.0 | 15.0 | 5.0 | 5.0 | 5.0 | 5.0 | 10.0 | 2.0 |

| | COMPOSITION (mol %) | | | | | | | HUMIDITY |
|---|---|---|---|---|---|---|---|---|
| No. | K₂O | P₂O₅ | Sb₂O₃ | ZrO₂ | CeO₂ | SO₂ | FF (%) | RESISTANCE |
| 43 | — | 6.0 | — | 0.5 | 0.6 | 0.1 | 77 | — |
| 44 | — | 6.0 | — | 0.5 | 0.6 | 1.0 | 77 | — |
| 45 | — | 6.0 | — | 0.5 | 0.6 | 1.0 | 77 | — |
| 46 | — | 6.0 | — | 0.5 | 0.6 | 1.0 | 77 | — |
| 47 | — | 6.0 | — | 0.5 | 0.6 | 1.0 | 77 | — |
| 48 | — | 6.0 | — | 0.5 | 0.6 | 5.0 | 75 | — |
| 49 | — | 2.0 | — | 1.0 | 0.8 | — | 76 | — |
| 50 | — | 2.0 | — | 0.5 | 0.5 | — | 77 | — |
| 51 | — | 2.0 | — | 0.5 | 0.5 | — | 77 | — |
| 52 | 1.0 | 1.0 | — | — | — | 0.5 | 77 | — |
| 53 | 1.0 | 1.0 | — | — | — | — | 77 | — |
| 54 | — | — | 1.0 | 1.0 | — | — | 75 | — |
| 55 | — | — | — | — | — | — | 75 | ◯ |
| 56 | — | 1.0 | — | 0.5 | 0.5 | — | 76 | — |
| 57 | — | 2.0 | — | 0.5 | 0.5 | — | 76 | — |
| 58 | — | — | — | — | — | 1.0 | 77 | — |
| 59 | — | 1.0 | — | 0.5 | 0.5 | — | 75 | — |

TABLE 4
[COMPARISON EXAMPLE]

| | COMPOSITION (mol %) | | | | | | | | | | |
|---|---|---|---|---|---|---|---|---|---|---|---|
| No. | Bi₂O₃ | B₂O₃ | SiO₂ | Al₂O₃ | ZnO | CaO | BaO | MgO | SrO | Li₂O | Na₂O |
| 18 | 27.0 | 15.0 | 15.0 | 2.0 | 20.0 | 1.0 | — | — | — | 13.0 | — |
| 19 | 22.0 | 12.0 | 20.0 | 2.0 | 12.0 | 5.0 | 5.0 | 6.0 | 5.0 | 10.0 | 1.0 |

| | COMPOSITION (mol %) | | | | | | | HUMIDITY |
|---|---|---|---|---|---|---|---|---|
| No. | K₂O | P₂O₅ | Sb₂O₃ | ZrO₂ | CeO₂ | SO₂ | FF (%) | RESISTANCE |
| 18 | — | — | — | — | — | 7.0 | 70 | — |
| 19 | — | — | — | — | — | — | 73 | — |

The conductive powder is prepared as commercially available spherical silver powder having, for example, an average particle diameter within the range of 0.5 to 3 (μm), for example, about 2 (μm). By using such silver powder having a sufficiently small average particle diameter, a filling rate of the silver powder is increased in an applied film and the electric conductivity of the conductor can consequently be increased. The vehicle is prepared by dissolving an organic binder in an organic solvent and, for example, butyl carbitol acetate and ethyl cellulose are used as the organic solvent and the organic binder, respectively. The proportion of ethyl cellulose in the vehicle is about 15 (wt %), for example. A solvent added separately from the vehicle is butyl carbitol acetate, for example. Although this is not a limitation, the solvent may be the same as that used for the vehicle. This solvent is added for the purpose of adjusting the viscosity of the paste.

After the paste raw materials described above are prepared and 80 parts by weight of the conductive powder, 10 parts by weight of the vehicle, appropriate amounts of other solvents and additives, and 2 to 6 (wt %) glass frit relative to the whole paste are weighed and mixed by using a stirring machine, etc., a dispersion process is executed by a three-roll mill, for example. As a result, the paste for an electrode is acquired. Tables 1 to 4 summarize the compositions of glass frits in the embodiments and the comparison examples and the evaluation results of the FF value and the humidity resistance of the solar cell 10 when the light-receiving surface electrode 28 is formed by using each of the glass frits.

While the paste for an electrode is prepared as described above, an impurity is dispersed or implanted in an appropriate silicon substrate with, for example, a well-known method such as a thermal diffusion method and ion implantation to form the n layer 22 and the p⁺ layer 24 to manufacture the silicon substrate 20. A silicon nitride (SiNₓ) thin film is then formed thereon with a suitable method, for example, spin coating, to dispose the antireflection film 26. In this embodiment, the 156 (mm)×156 (mm) rectangle silicon substrate 20 with the thickness dimension of 180 (μm) was used.

The paste for an electrode is then screen-printed in the pattern depicted in FIG. 2 on the antireflection film 26. The screen printing is performed by using a 325 mesh made of stainless steel. The paste is dried at 150 (degrees C.), for example, and is subjected to firing treatment at a temperature within the range of 650 to 900 (degrees C.) in a near-infrared furnace. As a result, since the glass component in the paste for an electrode melts the antireflection film 26 in the course of the firing and the paste for an electrode breaks the antireflection film 26, electric connection is achieved between the conductive component, i.e., silver, in the paste for an electrode and the n layer 22, and an ohmic contact is acquired between the silicon substrate 20 and the light-receiving surface electrode 28 as depicted in FIG. 1. The light-receiving surface electrode 28 is formed as described above.

The rear surface electrode 30 may be formed after the above operation or may be formed by firing at the same time as the light-receiving surface electrode 28. When the rear surface electrode 30 is formed, for example, an aluminum paste is applied to the entire rear surface of the silicon substrate 20 with a screen printing method etc., and is subjected to the firing treatment to form the entire surface electrode 34 consisting of an aluminum thick film. The paste for an electrode is then applied onto the surface of the entire surface electrode 34 in a belt shape by using the screen printing method etc., and is subjected to the firing treatment to form the belt-like electrode 36. As a result, the rear surface electrode 30 is formed that consists of the entire surface electrode 34 covering the entire rear surface and the belt-like electrode 36 disposed on a portion of the surface thereof in a belt shape, and the solar cell 10 is acquired. In the operation described above, if the concurrent firing is used for the fabrication, a printing process is executed before the firing of the light-receiving surface electrode 28.

The FF values of Tables 1 to 4 in the second column from the right are obtained by measuring output of the solar cell 10 acquired by forming the light-receiving surface electrode 28 through firing at each of firing temperatures recognized as the optimum temperatures for each of the embodiments and the comparison examples having variously modified glass compositions and additive amounts in the solar cell 10 acquired as described above. The output of the solar cell 10 was measured by using a commercially available solar simulator. The “humidity resistance” in the rightmost fields is obtained by an accelerated test in which the solar cell 10 is retained for 1000 hours under high temperature and high humidity at the temperature of 85 (degrees C.) and the humidity of 85(%) and indicated by a circle (with humidity resistance) when an FF change rate calculated by the following equation is within 2(%), by a triangle (with somewhat poor humidity resistance) when the FF change rate is 2 to 5(%), or by a cross mark (with poor humidity resistance) when the FF change rate exceeds 5(%).

FF change rate (%)=FF after humidity resistance test/FF before humidity resistance test×100

Although an FF value equal to or greater than 75(%) is desired for a solar cell, a higher FF value is naturally more preferable. The FF value equal to or greater than 75(%) is acquired from all the embodiments of Tables 1 and 3 and, particularly, the FF value equal to or greater than 76(%) is acquired from Nos. 2 to 4, 6 to 8, 11, 12, 15 to 18, 22 to 25, 27, 28, 30 to 32, 34 to 38, 40, 41, 43 to 47, 49 to 53, and 56 to 58 and, particularly, the high FF value of 77(%) is acquired from Nos. 2 to 4, 7, 8, 12, 16, 23, 24, 28, 34, 37, 40, 41, 43 to 47, 50 to 53, and 58, which confirms high characteristics equal to or greater than those in the case of using lead glass.

Although the humidity resistance was evaluated in a portion of the embodiments, only three embodiments are indicated by the triangle and the result indicated by the circle is acquired from most of the embodiments, which confirms that the embodiments also have extremely excellent humidity resistance.

On the other hand, all the comparison examples of Tables 2 and 4 are limited to an FF value equal to or less than 74(%) and five out of seven comparison examples evaluated in terms of humidity resistance have a result indicative of the absence of humidity resistance (cross mark).

The individual embodiments will hereinafter be described in detail. First, the embodiment Nos. 1 to 5 and the comparison example Nos. 1 and 2 were examined in terms of an appropriate Bi amount. The embodiments with the Bi amount within the range of 10.0 to 32.0 (mol %) result in the FF value equal to or greater than 75(%) and the humidity resistance indicated by the circle. The embodiments with the Bi amount from 15 to 28 (mol %) result in the FF value of 77(%). On the other hand, the comparison examples with 8 (mol %) or 34.0 (mol %) of the Bi amount are limited to the FF value from 73 to 74 (mol %). The humidity resistance is not evaluated. From these results, the Bi amount must be 10.0 to 32.0 (mol %). Since the embodiment No. 22 and the embodiment Nos. 2 to 4 result in the FF value equal to or greater than 76(%) and the humidity resistance indicated by the circle in the range of 15.0 to 30.0 (mol %), this range can be considered more preferable and, due to the embodiment Nos. 2 to 4, the range of 15 to 28 (mol %) can be considered particularly preferable.

The embodiment Nos. 6 to 9 and the comparison example Nos. 3 and 4 were examined in terms of an appropriate B amount. The embodiments with the B amount within the range of 5.0 to 18.0 (mol %) result in the FF value equal to or greater than 75(%) and the humidity resistance indicated by the triangle or better. The embodiments with the B amount from 8 to 16 (mol %) result in the FF value of 77(%) and the humidity resistance indicated by the circle. On the other hand, the comparison examples with 2 (mol %) or 20.0 (mol %) of the B amount are limited to the FF value of 74(%). The humidity resistance is evaluated as the cross mark. From these results, the B amount must be 5.0 to 18.0 (mol %) and is particularly preferably 8 to 16 (mol %).

The embodiment Nos. 10 to 13 and the comparison example Nos. 5 and 6 were examined in terms of an appropriate Zn amount. The embodiments with the Zn amount within the range of 15.0 to 30.0 (mol %) result in the FF value equal to or greater than 75(%) and the humidity resistance indicated by the triangle or better. The embodiments with the Zn amount from 21 to 26 (mol %) result in the FF value equal to or greater than 76(%) and the humidity resistance indicated by the circle. On the other hand, the comparison examples with 12 (mol %) or 32.0 (mol %) of the Zn amount are limited to the FF value of 74(%). The humidity resistance is evaluated as the cross mark. From these results, the Zn amount must be 15.0 to 30.0 (mol %). Since the embodiment Nos. 17 and 15 and the embodiment Nos. 11 to 12 result in the FF value equal to or greater than 76(%) in the range of 16.0 to 30.0 (mol %), this range can be considered more preferable and, since the embodiment Nos. 4, 7, 24, and 41 result in the FF value of 77(%) and the humidity resistance indicated by the circle in the range of 20.0 to 29.0 (mol %), this range can be considered particularly preferable.

The embodiment Nos. 14 to 17 and the comparison example Nos. 7 and 8 were examined in terms of an appropriate Si amount. The embodiments with the Si amount within the range of 15.0 to 26.0 (mol %) result in the FF value equal to or greater than 75(%) and the humidity resistance indicated by the triangle or better. The embodiments with the Si amount from 21 to 26 (mol %) result in the FF value equal to or greater than 76(%) and the humidity resistance indicated by the circle. On the other hand, the comparison examples with 12 (mol %) or 32.0 (mol %) of the Si amount are limited to the FF value of 74(%). The humidity resistance is evaluated as the cross mark. From these results, the Zn amount must be 15.0 to 30.0 (mol %). Since the embodiment Nos. 8, 16, 34, and 37 result in the FF value of 77(%) and the humidity resistance indicated by the circle in the range of 15.0 to 22.0 (mol %), this range can be considered particularly preferable.

The embodiment Nos. 18 to 20 and the comparison example Nos. 9 and 10 were examined in terms of an appropriate Al amount. The embodiments with the Al amount within the range of 2.0 to 10.0 (mol %) have the FF value equal to or greater than 75(%) and the humidity resistance indicated by the circle. On the other hand, the comparison examples with the Al amount of 0 (mol %) or 12.0 (mol %) are limited to the FF value of 74(%) and the humidity resistance is evaluated as the cross mark. From these results, the Al amount must be 2.0 to 10.0 (mol %). Since the embodiment Nos. 18, 27, and 28 result in the FF value equal to or greater than 76(%) and the humidity resistance indicated by the circle in the range of 2.0 to 5.5 (mol %), this range can be considered more preferable and, since the embodiment Nos. 2, 3, 4, 7, 28, etc. result in the FF value of 77(%) in the range of 3.0 to 5.5 (mol %), this range can be considered particularly preferable.

The embodiment Nos. 21 to 26 and the comparison example Nos. 11 and 12 were examined in terms of an appropriate alkali amount. The embodiments with the alkali amount within the range of 12.0 to 25.0 (mol %) result in the FF value equal to or greater than 75(%) and the humidity resistance indicated by the circle. On the other hand, the comparison examples with the alkali amount of 10 (mol %) or 27 (mol %) are limited to the FF value from 73 to 74(%) and, while the case of 10 (mol %) of the alkali amount results in the humidity resistance indicated by the circle, the case of 27 (mol %) of the alkali amount results in the humidity resistance indicated by the cross mark. From these results, the alkali amount must be the range of 12.0 to 25.0 (mol %). Since the embodiment Nos. 2 and 22 result in the FF value equal to or greater than 76(%) and the humidity resistance indicated by the circle in the range of the alkali amount from 13.0 to 21.5 (mol %), this range can be considered more preferable and, since the embodiment Nos. 2, 7, 8, 16, 23, etc. result in the FF value of 77(%)and the humidity resistance indicated by the circle in the range of the alkali amount from 14.0 to 21.5 (mol %), this range can be considered particularly preferable.

The embodiment Nos. 27 to 29 and the comparison example No. 13 were examined in terms of an appropriate P amount. The embodiments with the P amount within the range of 1.0 to 6.0 (mol %) result in the FF value equal to or greater than 75(%) and the humidity resistance indicated by the circle. On the other hand, the comparison example with the P amount of 8.0 (mol %) is limited to the FF value of 74(%). From these results, the P amount is preferably 1.0 to 6.0 (mol %) in the composition containing P. Since the embodiment Nos. 2, 28, 41, etc. result in the FF value of 77(%) and the humidity resistance indicated by the circle in the range of 0 to 3.0 (mol %), P is not an essential element and this range of the P amount can be considered particularly preferable.

The embodiment Nos. 30 to 33 and the comparison example No. 14 were examined in terms of an appropriate Sb amount. The embodiments with the Sb amount within the range of 1.0 to 4.0 (mol %) result in the FF value equal to or greater than 75(%) and the humidity resistance indicated by the circle. On the other hand, the comparison example with the Sb amount of 6.0 (mol %) is limited to the FF value of 74(%). Although Sb is not an essential element, from these results, the Sb amount is preferably 1.0 to 4.0 (mol %) in the composition containing Sb.

The embodiment Nos. 34 to 36 and the comparison example No. 15 were examined in terms of an appropriate Ti amount. The embodiments with the Ti amount within the range of 0.5 to 6.0 (mol %) result in the FF value equal to or greater than 76(%) and the humidity resistance indicated by the circle. On the other hand, the comparison example with the Ti amount of 8.0 (mol %) is limited to the FF value of 74(%). From these results, the Ti amount is preferably 0.5 to 6.0 (mol %) in the composition containing Ti. Since the embodiment Nos. 2, 34, 40, 41 etc. result in the FF value of 77(%) and the humidity resistance indicated by the circle in the range of 0 to 0.5 (mol %), Ti is not an essential element and is preferably limited to 0.5 (mol %) or less if contained.

The embodiment Nos. 37 to 39 and the comparison example No. 16 were examined in terms of an appropriate Zr amount. The embodiments with the Zr amount within the range of 0.5 to 5.0 (mol %) result in the FF value equal to or greater than 75(%) and the humidity resistance indicated by the circle. On the other hand, the comparison example with the Zr amount of 7.0 (mol %) is limited to the FF value of 73(%) and the humidity resistance indicated by the cross mark. From these results, the Zr amount is preferably 0.5 to 5.0 (mol %) in the composition containing Zr. Since the embodiment Nos. 2, 37, etc. result in the FF value of 77(%) and the humidity resistance indicated by the circle in the range of 0 to 0.5 (mol %), Zr is not an essential element and is preferably limited to 0.5 (mol %) or less if contained.

The embodiment Nos. 40 to 42 and the comparison example No. 17 were examined in terms of an appropriate Ce amount. The embodiments with the Ce amount within the range of 0.1 to 5.0 (mol %) result in the FF value equal to or greater than 75(%) and the humidity resistance indicated by the circle. On the other hand, the comparison example with the Ce amount of 7.0 (mol %) is limited to the FF value of 73(%). From these results, the Ce amount is preferably 0.1 to 5.0 (mol %) in the composition containing Ce. Since the embodiment Nos. 7, 40, 41, etc. result in the FF value of 77(%) and the humidity resistance indicated by the circle in the range of 0 to 2.0 (mol %), Ce is not an essential element and is preferably limited to 2.0 (mol %) or less if contained.

The embodiment Nos. 43 to 48 and the comparison example No. 18 were examined in terms of the composition containing S. No. 43 contains 0.1 (mol %) SO_{2;} Nos. 44 to 47 contain 1.0 (mol %) SO₂; No. 48 contains 5.0 (mol %) SO₂; and the high FF value of 75(%) or larger is acquired in all the cases. Although not an essential component, SO₂ has an effect of reducing the viscosity of glass. However, if SO₂ exceeds 6 (mol %), since the softening point becomes too high and the antireflection film is hardly eroded, a favorable ohmic contact cannot be acquired. The comparison example No. 18 containing 7.0 (mol %) SO₂ results in the FF value of 70(%). Therefore, if SO₂ is contained, the amount of SO₂ is appropriately equal to or less than 6 (mol %), for example, within the range of 0.1 to 6 (mol %), desirably within the range of 0.1 to 5 (mol %), and more desirably within the range of 0.1 to 2 (mol %). The embodiment Nos. 44 to 46 contain at least one of the alkaline-earth oxides CaO, BaO, MgO, and SrO in addition to SO₂ and all result in the high FF value of 77(%).

The embodiment Nos. 49 to 59 and the comparison example No. 19 were examined in terms of the composition containing alkali earths. Although not essential elements, alkaline-earth oxides CaO, BaO, MgO, and SrO have effects of lowering the softening point of glass and suppressing the crystallization of glass. However, if a total of the alkaline-earth oxides exceeds 20 (mol %), the chemical durability is reduced and, therefore, the total amount is set to 20 (mol %) or less. No. 49 contains 0.2 (mol %) CaO and results in the FF value of 76(%). No. 50 contains 2.0 (mol %) BaO; No. 51 contains 6.0 (mol %) BaO; No. 52 contains 7.0 (mol %) BaO and 8.0 (mol %) MgO making a total of 15.0 (mol %); No. 53 contains 5.0 (mol %) CaO and 10.0 (mol %) BaO making a total of 15.0 (mol %); and the high FF value of 77(%) is acquired in each of the cases. No. 54 contains 6.0 (mol %) CaO and BaO making a total of 12.0 (mol %); No. 55 contains 2.0 (mol %) CaO and 3.0 (mol %) BaO making a total of 5.0 (mol %); and the FF value of 75(%) is acquired in the both cases. No. 56 contains 10.0 (mol %) MgO; No. 57 contains 4.0 (mol %) BaO and 6.0 (mol %) SrO making a total of 10.0 (mol %); and the FF value is 76(%) in the both cases. No. 58 contains 2.0 (mol %) CaO, 3.0 (mol %) BaO, and 2.0 (mol %) MgO making a total of 7.0 (mol %), and results in the FF value of 77(%). No. 59 contains 5.0 (mol %) CaO, BaO, SrO, and MgO making a total of 20 (mol %), and results in the FF value of 75(%). No. 55 is also evaluated in terms of the humidity resistance and results in the preferable FF change rate equal to or less than 2(%). On the other hand, the comparison example No. 19 contains 5.0 (mol %) CaO, BaO, and SrO and 6.0 (mol %) MgO making a total of 21 (mol %), and results in the FF value of 73(%). From these results, it is confirmed that even when the composition contains the alkali earths, sufficiently high characteristics can be achieved if the total amount is equal to or less than 20 (mol %), for example, within the range of 0.1 to 20 (mol %). The embodiment Nos. 52 and 58 contain SO₂ in addition to the alkali earths and result in the high FF value of 77(%) in the both cases. The comparison example No. 19 is also a comparison example containing Li₂O, Na₂O, and K₂O in a total alkali amount of 11.0 (mol %), which is out of the appropriate range of 12 to 25 (mol %).

As described above, since the conductive paste for a solar cell of this embodiment is made up of the glass frit comprising lead-free glass having composition with Bi₂O₃ from 10 to 32 (mol %), ZnO from 15 to 30 (mol %), SiO₂ from 15 to 26 (mol %), B₂O₃ from 5 to 18 (mol %), Li₂O, Na₂O, and K₂O from 12 to 25 (mol %) in total, Al₂O₃ from 2 to 10 (mol %), TiO₂ from 0 to 6 (mol %), ZrO₂ from 0 to 5 (mol %), P₂O₅ from 0 to 6 (mol %) and Sb₂O₃ from 0 to 4 (mol %) such that P and Sb make a total of 0 to 6 (mol %), CeO₂ from 0 to 5 (mol %), and arbitrary components that are alkaline-earth oxides CaO, BaO, MgO, and SrO equal to or less than 20 (mol %) in total and SO₂ equal to or less than 6 (mol %), when the light-receiving surface electrode 28 of the solar cell 10 is formed by using this paste, the electrode can advantageously be acquired that has the FF value equal to or greater than 75(%), i.e., excellent electrical characteristics, and high humidity resistance even though the electrode is lead-free. It is inferred that such an effect is acquired because of sufficiently high SiO₂, the inclusion of Al₂O₃, and low B₂O₃.

Although the present invention has been described in detail with reference to the drawings, the present invention may also be implemented in other forms and may variously be modified within a range not departing from the spirit thereof.

For example, although the antireflection film 26 consists of a silicon nitride film in the embodiment, the constituent material is not particularly limited and the antireflection film may be made of various other materials such as titanium dioxide TiO₂, which is generally used for solar cells, and may be used in the same way.

Although the present invention is applied to the silicon-based solar cell 10 in the description of this embodiment, the present invention is not particularly limited in terms of a substrate material of an application object as long as a solar cell has a light-receiving surface electrode that can be formed by the fire-through method.

Although not exemplarily illustrated one by one, the present invention may be implemented in variously modified and improved forms based on the knowledge of those skilled in the art.

### NOMENCLATURE OF ELEMENTS

10: solar cell 12: solar cell module 14: sealing material 16: surface glass 18: protective film 20: silicon substrate 22: n layer 24: p+ layer 26: antireflection film 28: light-receiving surface electrode 30: rear surface electrode 32: light-receiving surface 34: entire surface electrode 36: belt-like electrode

1. A lead-free conductive paste composition for a solar cell containing a conductive powder, a glass frit, and a vehicle,
the glass frit comprising at least one type of lead-free glass containing
Bi₂O₃ from 10 to 32 (mol %), ZnO from 15 to 30 (mol %), SiO₂ from 15 to 26 (mol %), B₂O₃ from 5 to 18 (mol %), Li₂O, Na₂O, and K₂O from 12 to 25 (mol %) in total, Al₂O₃ from 2 to 10 (mol %), TiO₂ from 0 to 6 (mol %), ZrO₂ from 0 to 5 (mol %),
0 to 6 (mol %) P₂O₅ and 0 to 4 (mol %) Sb₂O₃ making a total of 0 to 6 (mol %), and
CeO₂ from 0 to 5 (mol %) at proportions within the respective ranges relative to the whole glass composition in terms of oxide.

2. The lead-free conductive paste composition for a solar cell of claim 1, wherein the lead-free glass contains one or more of BaO, CaO, MgO, and Sr0 within a range equal to or less than 20 (mol %) in total relative to the whole glass composition in terms of oxide.

3. The lead-free conductive paste composition for a solar cell of claim 1, wherein the lead-free glass contains SO₂ within a range equal to or less than 6 (mol %) relative to the whole glass composition in terms of oxide.
